(19) United States
(12) Patent Application Publication
(10) Pub. No.: US 2012/0133634 A1
(43) Pub. Date: May 31, 2012

(54) APPARATUS, SYSTEM, AND METHOD FOR GENERATING A LOW POWER SIGNAL WITH AN OPERATIONAL AMPLIFIER

(75) Inventors: June Her, Tucson, AZ (US); Andrew Luchsinger, Tucson, AZ (US); Marc Kobayashi, Oro Valley, AZ (US); Paul Brokaw, Tucson, AZ (US)

(73) Assignee: INTEGRATED DEVICE TECHNOLOGY, INC., San Jose, CA (US)

(21) Appl. No.: 12/956,928

(22) Filed: Nov. 30, 2010

(51) Int. Cl. G09G 5/00; H03F 3/45; H03F 1/34

(52) U.S. Cl. 345/212; 330/102; 330/260

(57) ABSTRACT

An amplifier, electronic display system, and a related method for generating a low power signal with an operational amplifier are disclosed herein. An embodiment of the present invention includes an amplifier, comprising an operational amplifier and a voltage converter. The operational amplifier includes an inverting input, a non-inverting input, an output, a first power supply input and a second power supply input, and is configured to generate an output signal in response to an input signal. The voltage is operably coupled with the first power supply input of the operating amplifier, and is configured to receive a first supply voltage and generate a second supply voltage to the first power supply input of the operational amplifier. The voltage of the second supply voltage is relatively closer to the expected operating voltage range of the output signal than is the first supply voltage.

### TECHNICAL FIELD

Embodiments of the present disclosure relate generally to operational amplifiers and, more particularly, to apparatuses and methods related to reducing power dissipation during the operation of an operational amplifier.

### BACKGROUND

Operational amplifiers may be employed in a wide range of electronic circuits. Operational amplifiers may be employed as inverting amplifiers, amplifiers, comparators, buffers, as well as in many other configurations to achieve a desired operation. Operational amplifiers may, for example, be employed in a driver circuit and provide a voltage to another circuit, such as in providing a common reference voltage (V_{COM}) used in liquid crystal displays (LCDs).

FIG. 1 is a schematic of a conventional amplifier 100. Conventional amplifier 100 includes an operational amplifier 110 including an inverting input 112, a non-inverting input 114, a first power supply input 116, a second power supply input 118, and an output 120. The inverting input 112 and the non-inverting input 114 may collectively be referred to as inputs 112, 114. The first power supply input 116 and the second power supply input 118 may collectively be referred to as power supply inputs 116, 118. The conventional amplifier 100 may be configured as a buffer (i.e., voltage follower) in that the inverting input 112 is operably coupled with the output 120. The first power supply input 116 may be coupled with a supply voltage (V_{SUPPLY1}). The second power supply input 118 may be coupled with a different supply voltage, such as ground (GND).

In operation, the operational amplifier 110 may receive an input signal (V_{IN}) at the non-inverting input 114. The conventional amplifier 100 generates an output signal (V_{OUT}) in response to the input signal (V_{IN}). Because the inverting input 112 is coupled with the output 120, the voltage at the inverting input 112 may be approximately equal to the voltage of the output signal (V_{OUT}) at the output 120. Because of the direct feedback loop from the output 120 to the inverting input 116, the output signal (V_{OUT}) is also approximately equal to the input signal (V_{IN}) at the non-inverting input 114 when the output signal (V_{OUT}) reaches a steady state.

As is known in the art, the internal construction of the operational amplifier 110 may cause the output signal (V_{OUT}) to operate at a voltage that is between voltages at the power supply inputs 116, 118. In other words, the operational amplifier 110 may operate within a linear region when the input signal (V_{IN}) received by the non-inverting input 114 is at a voltage between the voltage range of the power supply inputs 116, 118. If the input signal (V_{IN}) at the non-inverting input 114 is at a voltage that exceeds the voltage range of the power supply inputs 116, 118, then the operational amplifier 110 may saturate, and the output signal (V_{OUT}) is approximately equal to the voltage of the appropriate one of the power supply inputs 116, 118.

For ease of discussion, it will be assumed that the voltage at the first power supply input 116 is represented as the supply voltage (V_{SUPPLY}) and the voltage of the second power supply input 118 is 0V (i.e., coupled with ground). In that situation, the power dissipation (P) for the operational amplifier 110, when configured as shown in FIG. 1, is approximately:

P=(V_{SUPPLY}−V_{OUT})*I_{OUT} (1).

Therefore, when V_{OUT} is less than V_{SUPPLY1} power is dissipated. For example, if V_{SUPPLY}=8V, V_{OUT}=3.8V, and I_{OUT}=20 mA, then P=84 mW. Such a power dissipation (P) may unnecessarily waste power as well as cause an increase in the operating temperature of the operational amplifier 110. In order to reduce the increased temperature of the operational amplifier 110, previous solutions have focused on improving the thermal characteristics of the operational amplifier 110 design, package, or printed circuit board layout. However, such solutions may not sufficiently improve the power dissipation.

### BRIEF SUMMARY OF THE INVENTION

Embodiments of the present invention include an amplifier, comprising an operational amplifier and a voltage converter. The operational amplifier includes an inverting input, a non-inverting input, an output, a first power supply input and a second power supply input, and is configured to generate an output signal in response to an input signal. The voltage is operably coupled with the first power supply input of the operating amplifier, and is configured to receive a first supply voltage and generate a second supply voltage to the first power supply input of the operational amplifier. The voltage of the second supply voltage is relatively closer to the expected operating voltage range of the output signal than is the first supply voltage.

Another embodiment of the present invention includes a method for operating an operational amplifier. The method comprises receiving an input signal at an input of an operational amplifier, generating an output signal at an output of the operational amplifier in response to receiving the input signal, receiving a first supply voltage, generating a second supply voltage in response to receiving the first supply voltage, and supplying the second supply voltage to a first power supply input of the operational amplifier. The second supply voltage is relatively closer to a voltage level of the output signal than is the first supply voltage.

Yet another embodiment of the present invention includes an electronic display system. The electronic display system includes a pixel array, a boost regulator configured to generate a boost signal, an operational amplifier operably coupled between the boost regulator and the pixel array, and a voltage converter operably coupled between the boost regulator and a first power supply input of the operational amplifier. The operational amplifier is configured to generate a common voltage reference signal to the pixel array. The voltage converter is configured to receive the boost signal and generate a supply voltage to the first power supply input of the operational amplifier, wherein the supply voltage has a voltage that is relatively closer to a voltage of the common voltage reference signal than does a voltage of the boost signal.

### BRIEF DESCRIPTION OF THE SEVERAL VIEWS OF THE DRAWINGS

FIG. 1 is a schematic of a conventional amplifier;

FIG. 2 illustrates an amplifier according to an embodiment of the present invention;

FIG. 3A illustrates a voltage converter according to an embodiment of the present invention;

FIG. 3B illustrates a voltage converter configured as a booster according to an embodiment of the present invention;

FIG. 3C illustrates a voltage converter configured as a splitter according to an embodiment of the present invention;

FIG. 4 illustrates an amplifier according to an embodiment of the present invention;

FIG. 5 is a simplified block diagram of a portion of an electronic display system according to an embodiment of the present invention;

FIG. 6 is a simplified block diagram of a portion of an electronic display system according to an embodiment of the present invention; and

FIG. 7 is a flow chart illustrating a method for generating a signal from an operational amplifier according to an embodiment of the present invention.

### DETAILED DESCRIPTION

In the following description, elements, circuits, and functions may be shown in block diagram form for ease of discussion. Conversely, specific implementations shown and described are exemplary only and should not be construed as the only way to implement the present invention unless specified otherwise herein. Additionally, block definitions and partitioning of logic between various blocks is exemplary of a specific implementation. It will be readily apparent to one of ordinary skill in the art that the present invention may be practiced by numerous other partitioning solutions. For the most part, details concerning timing considerations and the like have been omitted where such details are not necessary to obtain a complete understanding of the present invention and are within the abilities of persons of ordinary skill in the relevant art.

Furthermore, in this description of embodiments of the invention, reference is made to the accompanying drawings which form a part hereof, and in which is shown, by way of illustration, specific embodiments in which the invention may be practiced. The embodiments are intended to describe aspects of the invention in sufficient detail to enable those skilled in the art to practice the invention. Other embodiments may be utilized and changes may be made without departing from the scope of the present invention. The following detailed description is not to be taken in a limiting sense and the scope of the present invention is defined only by the appended claims.

It should be understood that any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise a set of elements may comprise one or more elements.

There is a need for methods and apparatuses to reduce the power dissipation during operation of an operational amplifier, which reduction of the power dissipation may also reduce the temperature of the operational amplifier during operation. Such methods and apparatuses may be particularly advantageous when implemented as a V_{COM} driver of a LCD system. Such a LCD system may include LCD monitors for stationary devices, as well as portable hand-held devices that include electronic displays.

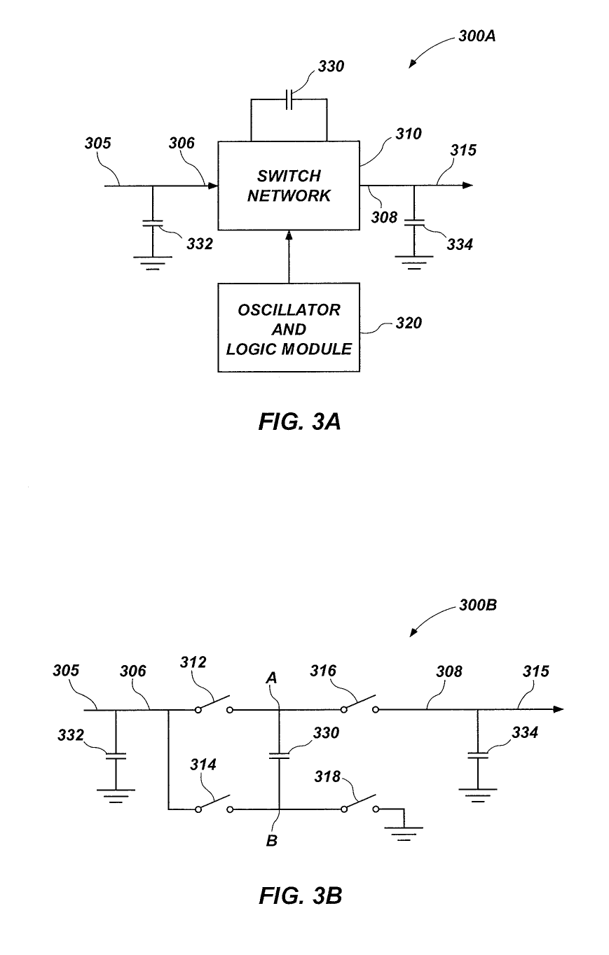

FIG. 2 illustrates an amplifier 200 according to an embodiment of the present invention. The amplifier 200 includes an operational amplifier 210 and a voltage converter 230. The operational amplifier 210 includes an inverting input 212 and a non-inverting input 214 that may collectively be referred to herein as inputs 212, 214. The operational amplifier 210 further includes a first power supply input 216 and a second power supply input 218 that may collectively be referred to as power supply inputs 216, 218. The operational amplifier 210 further includes an output 220. The operational amplifier 210 may be configured as a voltage follower with the inverting input 212 coupled with the output 220. Other configurations of the operational amplifier 210 are also contemplated, and may include an amplifier gain that is different from the unity gain shown in the several embodiments that are described herein.

The first power supply input 216 may be configured to receive a greater voltage than the second power supply input 218. For example, the second power supply input 218 may be coupled with ground while the first power supply input 216 is coupled with a positive voltage. Other configurations are also contemplated in which the second power supply input 218 is not coupled with ground (GND), and where one or both of the power supply inputs 216, 218 has a negative voltage relative to ground (GND).

The operational amplifier 210 may be configured to generate an output signal (V_{OUT}) at the output 220 that is limited to operate within the voltage range of the at the power supply inputs 216, 218. For example, as configured in FIG. 2, the output signal (V_{OUT}) generally follows an input signal (V_{IN}) received by the non-inverting input 214 if the voltage of the input signal (V_{IN}) is within the voltage range of the power supply inputs 216, 218. If the input signal (V_{IN}) received by the non-inverting input 214 has a voltage outside of the voltage range of the power supply inputs 216, 218, the operational amplifier 210 may saturate and the output signal (V_{OUT}) is limited by the voltage of the appropriate power supply inputs 216, 218.

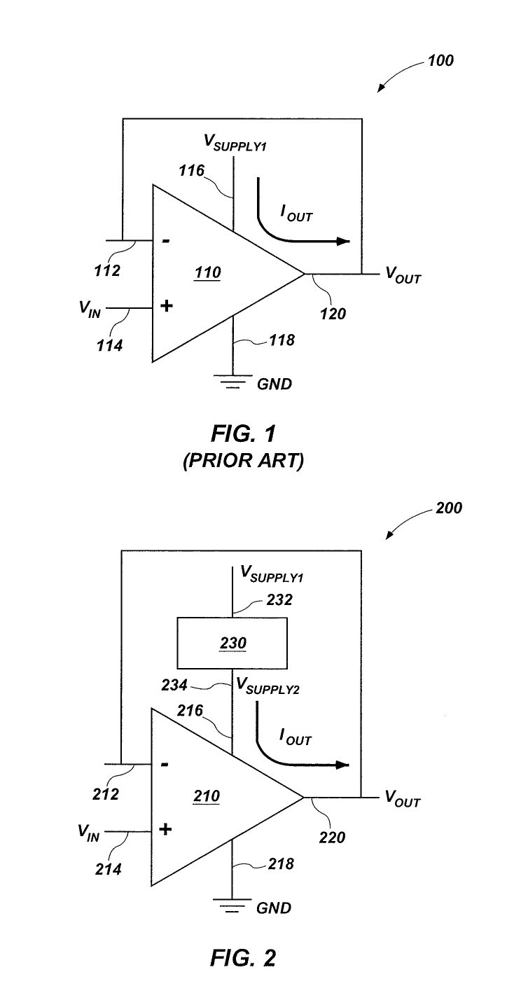

The voltage converter 230 may include an input 232 and an output 234. The output 234 of the voltage converter 230 is coupled with the first power supply input 216 of the operational amplifier 210. The input 232 of the voltage converter 230 may be coupled with a first supply voltage (V_{SUPPLY1}), which in a conventional amplifier (e.g., FIG. 1) would have otherwise been coupled directly with the first power supply input 216. In operation, the voltage converter 230 receives the first supply voltage (V_{SUPPLY1}) and generates a second supply voltage (V_{SUPPLY2}) in response thereto. As a result, the second supply voltage (V_{SUPPLY2}) is received by the first power supply input 216 of the operational amplifier 210. The second power supply input 218 may be coupled with a third supply voltage, which is shown as ground (GND) in FIG. 2.

The second supply voltage (V_{SUPPLY2}) may have a voltage that is converted from the first supply voltage (V_{SUPPLY1}) such that the second supply voltage (V_{SUPPLY2}) is relatively closer to the expected operating voltage range of the output signal (V_{OUT}) than is the first supply voltage (V_{SUPPLY1}). In other words, the difference between the voltage of the second supply voltage (V_{SUPPLY2}) and the output signal (V_{OUT}) is closer to 0V than the difference between first supply voltage (V_{SUPPLY1}) and the output signal (V_{OUT}). As a result, the configuration of the amplifier 200 may reduce the power dissipated by the operational amplifier 210 as compared with the power dissipation of a conventional amplifier (e.g., FIG. 1). For example, the power dissipation (P) for the operational amplifier 210, when configured as shown in FIG. 2, is approximately:

P=(V_{SUPPLY2}−V_{OUT})*I_{OUT} (2).

When the voltage of the output signal (V_{OUT}) is less than the second supply voltage (V_{SUPPLY2}), power (P) may be dissipated. However, when the voltage of the second supply voltage (V_{SUPPLY2}) is relatively closer to the expected operating voltage range of the output signal (V_{OUT}) than is the voltage of the first supply voltage (V_{SUPPLY1}), the power dissipated (P) by the operational amplifier 210 may be reduced as compared with the power dissipation (P) of the conventional amplifier (e.g., FIG. 1). For example, if V_{SUPPLY1}=8V, V_{SUPPLY2}=4V, V_{OUT}=3.8V, and I_{OUT}=20 mA, then P=4 mW. Such a power dissipation (P) may reduce the power wasted by the amplifier configuration of FIG. 1. For example, the power dissipation (P) for the example associated with equation (1) is 80 mW more than the power dissipation (P) for the example associated with equation (2).

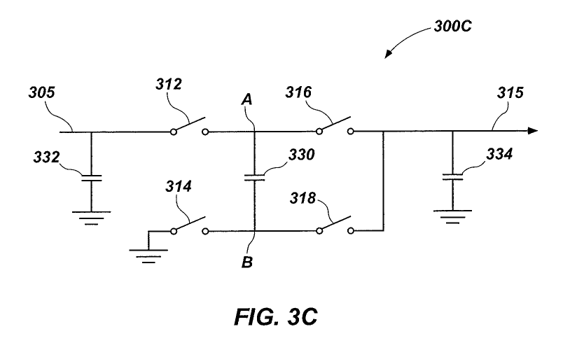

FIG. 3A illustrates a voltage converter 300A according to an embodiment of the present invention. The voltage converter 300A may, for example, be employed with the amplifier 200 as the voltage converter 230 in FIG. 2. The voltage converter 300A may be configured as a charge pump that includes a switch network 310, an oscillator and logic module 320, and a plurality of capacitors 330, 332, 334. The switch network includes a plurality of switches (not shown; see FIGS. 3B and 3C) that are configured to toggle between charging and discharging the first capacitor 330 according to the control signals received from the oscillator and logic module 320. The first capacitor 330 may be referred to as a “flying capacitor.” Embodiments are not to be viewed as being limited to a single flying capacitor 330 or switch network 310. Some embodiments may include a plurality of flying capacitors 330 and a plurality of switch networks 310. The second capacitor 332 may be configured as a bypass capacitor that is coupled with an input 306 of the switch network 310 to reduce input noise to the voltage converter 300A. The second capacitor 332 may also be referred to as an “input capacitor.” The third capacitor 334 may be coupled with an output 308 of the switch network 310. The third capacitor 334 may be referred to as a “load capacitor.”

The voltage converter 300A may be configured to convert an input signal 305 received by the switch network 330 and generate an output signal 315 in response thereto. The output signal 315 may be different from the input signal 305. In particular, the voltage converter 300A may be configured as a booster or a splitter. In some embodiments, the voltage converter 300A may be configured as an inverter.

When the voltage converter 300A is configured as a booster, the output signal 315 may be increased from the input signal 305 by some amount. For example, the output signal 315 may be an integer multiple (e.g., 2×, 3×, etc.) of the input signal 305. Additionally, the output signal 315 may be a fractional multiple (e.g., 3/2×, 4/3×, etc.) of the input signal 305. Alternatively, when the voltage converter 300A is configured as a splitter, the output signal 315 may be decreased from the input signal 305 by some amount. For example, the output voltage may be fractionally scaled (e.g., ⅓×, ½×, ⅔×, etc.) from the input signal 305.

FIG. 3B illustrates a voltage converter 300B configured as a booster according to an embodiment of the present invention. The voltage converter 300B may, for example, be employed with amplifier 200 as the voltage converter 230 in FIG. 2. The voltage converter 300B includes a plurality of switches 312, 314, 316, 318, and a plurality of capacitors 330, 332, 334. The plurality of switches 312, 314, 316, 318 may represent a more detailed view of the switch network 310 of FIG. 3A; however, embodiments of the present invention should not be viewed as limited to this particular configuration, or to include only these particular components.

The oscillator and logic module 320 (FIG. 3A) is not shown in FIG. 3B for simplicity; however, activation of the plurality of switches 312, 314, 316, 318 may be controlled by the oscillator and logic module 320. Individually, the plurality of switches 312, 314, 316, 318 may be referred to as a first switch 312, a second switch 314, a third switch 316, and a fourth switch 318. As previously discussed, the plurality of capacitors 330, 332, 334 may individually be referred to as a flying capacitor 330, an input capacitor 332, and a load capacitor 334.

In the configuration shown in FIG. 3B, the first switch 312 and the third switch 316 are serially coupled between the input signal 305 and the output signal 315. The second switch 314 and the fourth switch 318 are serially coupled between the input signal 305 and ground (GND). The flying capacitor 330 is coupled between the nodes A, B between the transistors 312, 316 and the transistors 314, 318. The input capacitor 332 is coupled between the input signal 305 and ground (GND), and the load capacitor 334 is coupled between the output signal 315 and ground (GND).

In operation, the voltage converter 300B may convert the input signal 305 of a relatively low voltage to an output signal 315 of a relatively higher voltage. In other words, the voltage converter 300B may receive the input signal 305 and generate the output signal 315 with a relatively higher voltage in response thereto. In particular, the first switch 312 and the fourth switch 318 may be closed while the second switch 314 and the third switch 316 are open. In that situation, the flying capacitor 330 is charged. When a discharge control signal is given, the first switch 312 and the fourth switch 318 are closed while the second switch 314 and the third switch 316 are open. This action discharges the flying capacitor 330 and charges the load capacitor 334 to a voltage relatively greater than the input signal 305 (e.g., 2×, etc.).

FIG. 3C illustrates a voltage converter 300C configured as a splitter according to an embodiment of the present invention. The voltage converter 300C may, for example, be employed with amplifier 200 as the voltage converter 230 in FIG. 2. The voltage converter 300C includes a plurality of switches 312, 314, 316, 318, and a plurality of capacitors 330, 332, 334. The plurality of switches 312, 314, 316, 318 may be a more detailed view of the switch network 310 of FIG. 3A. The oscillator and logic module 320 (FIG. 3A) is not shown in FIG. 3C for simplicity; however, activation of the plurality of switches 312, 314, 316, 318 may be controlled by the oscillator and logic module 320. Individually, the plurality of switches 312, 314, 316, 318 may be referred to as a first switch 312, a second switch 314, a third switch 316, and a fourth switch 318. Individually, the plurality of capacitors may be referred to as a flying capacitor 330, an input capacitor 332, and a load capacitor 334.

In the configuration shown in FIG. 3C, the first switch 312 and the third switch 316 are serially coupled between the input signal 305 and the output signal 315. The second switch 314 and the fourth switch 318 are serially coupled between ground (GND) and the output signal 315. The flying capacitor 330 is coupled between the nodes A, B between the transistors 312, 316 and the transistors 314, 318. The input capacitor 332 is coupled between the input signal 305 and ground (GND), and the load capacitor 334 is coupled between the output signal 315 and ground (GND).

In operation, the voltage converter 300C may convert the input signal 305 of a relatively high voltage to an output signal 315 of a relatively lower voltage. In other words, the voltage converter 300B may receive the input signal 305 and generate the output signal 315 with a relatively lower voltage in response thereto. In particular, the first switch 312 and the fourth switch 318 may be closed while the second switch 314 and the third switch 316 are open. In that situation, the voltage drop across the flying capacitor 330 charges to a voltage difference between the input signal 305 and the output signal 315. When a discharge control signal is given, the first switch 312 and the fourth switch 318 are closed while the second switch 314 and the third switch 316 are open. This action discharges the flying capacitor 330 and charges the load capacitor 334 to a voltage relatively lower than the input signal 305 (e.g., ½×, etc.).

While FIGS. 3A through 3C illustrate voltage converters that are configured as charge pumps, embodiments of the present invention may also include other configurations of voltage regulators, such as, for example, boost converters, buck converters, and low-dropout (LDO) voltage regulators.

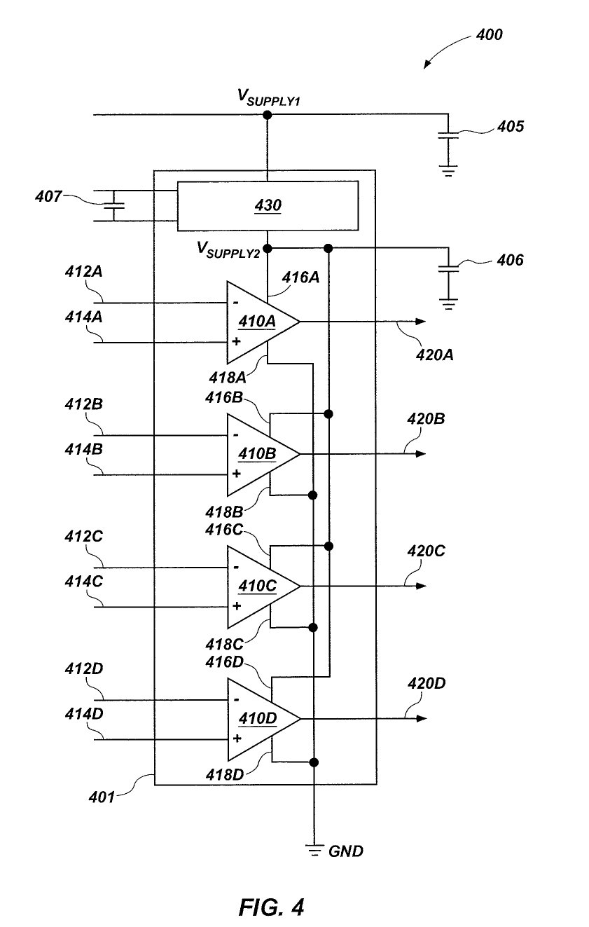

FIG. 4 illustrates an amplifier 400 according to an embodiment of the present invention. The amplifier 400 includes a plurality of operational amplifiers 410A-D, and a voltage converter 430. Each operational amplifier 410A-D of the plurality includes an inverting input 412A-D, a non-inverting input 414A-D, a first power supply input 416A-D, a second power supply input 418A-D, and an output 420A-D. If configured as a buffer (i.e., voltage follower), the inverting inputs 412A-D may be coupled with the respective outputs 420A-D. Each operational amplifier 410A-D of the plurality may be configured as a buffer independently of the other operational amplifiers 410A-D of the plurality. For example, the first operational amplifier 410A may be configured as a buffer, while the other operational amplifiers 410B-D need not be configured as buffers.

The voltage converter 430 is coupled with a first power supply input 416A-D for each of the plurality of operational amplifiers 410A-D. The voltage converter 430 may be configured to receive a first supply voltage (V_{SUPPLY1}) and generate a second supply voltage (V_{SUPPLY2}), such that the second supply voltage (V_{SUPPLY2}) is received by the first power supply input 416A-D of each of the plurality of operational amplifiers 410A-D. The second power supply input 418A-D for each of the plurality of operational amplifiers 410A-D may be coupled with a third supply voltage that has a reduced voltage from the second supply voltage (V_{SUPPLY2}). For example, the third supply signal may be 0V (i.e., ground (GND)).

The voltage converter 430 may be configured such that the second supply voltage (V_{SUPPLY2}) generated by the voltage converter 430 is relatively closer to the expected operating voltage of the output signal (V_{OUT}) than is the first supply voltage (V_{SUPPLY1}). In other words, the difference between the voltage of the second supply voltage (V_{SUPPLY2}) and the output signal (V_{OUT}) is closer to 0V than the difference between first supply voltage (V_{SUPPLY1}) and the output signal (V_{OUT}).

The plurality of operational amplifiers 410A-D and the voltage converter 430 may be housed within a common package 401. Additionally, the plurality of operational amplifiers 410A-D and the voltage converter 430 may be fabricated within a common integrated circuit. Of course, a voltage converter and a single operational amplifier (FIG. 2) may also be housed within a common package. Alternatively, the plurality of operational amplifiers 410A-D (or single operational amplifier) and the voltage converter 430 may be configured as discrete components.

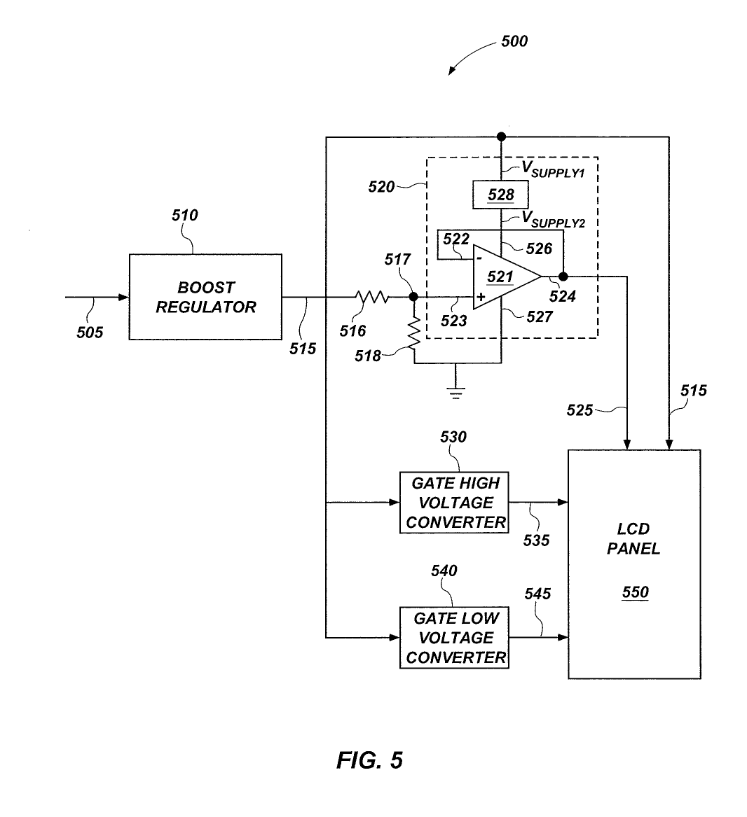

FIG. 5 is a simplified block diagram of a portion of an electronic display system 500 according to an embodiment of the present invention. The electronic display system 500 may be, for example, a LCD system. The electronic display system 500 includes a boost regulator 510, a V_{COM} driver 520, a gate high voltage converter 530, a gate low voltage converter 540, and a LCD panel 550. The electronic display system 500 may include other components that are not shown for simplicity, but that would nevertheless be understood by those skilled in the art.

The boost regulator 510 is operatively coupled with the V_{COM} driver 520. The boost regulator 510 may be further coupled with other components of the electronic display system 500, such as the gate high voltage converter 530, the gate low voltage converter 540, and the LCD panel 550. The boost regulator 510 may be configured to receive an input signal 505 to the electronic display system 500 and generate a boost signal 515 in response thereto. The boost signal 515 may be a “stepped up” (i.e., “boosted”) voltage from the input signal 505, and may provide a relatively greater drive for the components receiving the boost signal 515.

The V_{COM} driver 520 may include an operational amplifier 521 including an inverting input 522, a non-inverting input 523, an output 524, a first power supply input 526, and a second power supply input 527. The operational amplifier 521 may be configured as a buffer (i.e., voltage follower). That is, the inverting input 522 of the operational amplifier 521 is coupled with the output 524 of the operational amplifier 521. The non-inverting input 523 of the operational amplifier 521 is coupled with an input signal 516 that controls the desired operating condition of the output signal (i.e., V_{COM} signal 525). Other configurations of the operational amplifier are also contemplated, which may include gains other than the unity gain buffer configuration illustrated. Resistors 516, 518 may be configured as a voltage divider to generate the desired voltage for the input signal 517 to the operational amplifier 521. As a result, the input signal 517 may be a lower voltage than the boost signal 515.

The V_{COM} driver 520 further includes a voltage converter 528 coupled with the first power supply input 526. The voltage converter 528 is configured to receive a first supply voltage (V_{SUPPLY1}) and generate a second supply voltage (V_{SUPPLY2}). It is noted that the boost signal 515 is the same signal as the first supply voltage (V_{SUPPLY1}) in this configuration. While an operational amplifier of a conventional electronic display system had previously received the boost signal 515 directly at the first power supply input 526, the second supply voltage (V_{SUPPLY2}) is applied to the first power supply input 526. The second power supply input 527 may be coupled with a third supply voltage, which in FIG. 5 is coupled with ground (GND). The V_{COM} signal 525 is generated in response to the input signal 517, and may be used as a common reference voltage to the LCD panel 550.

As previously discussed, the voltages applied to the first power supply input 526 and a second power supply input 527 permit the operational amplifier 521 to operate within a voltage range before saturation occurs. The second supply voltage (V_{SUPPLY2}) may have a voltage level that is relatively closer to the expected operating voltage range of the V_{COM} signal 525 than is the boost signal 515. For example, the boost signal may be 8V and the desired and expected operating range of the V_{COM} signal 525 may be 3.8V. If the boost signal 515 were directly coupled with the first power supply input 526, a relatively high amount of power dissipation may be experienced as described in equation (1) for a conventional amplifier (FIG. 1). The voltage converter 528 may be configured to reduce the boost signal 515 by a factor of one half, and the second supply voltage (V_{SUPPLY2}) may be approximately 4V. As a result, the power dissipation may be relatively low as described in equation (2). In some embodiments, the difference between the second supply voltage (V_{SUPPLY2}) and the expected operating voltage of the V_{COM} signal 525 may be approximately zero.

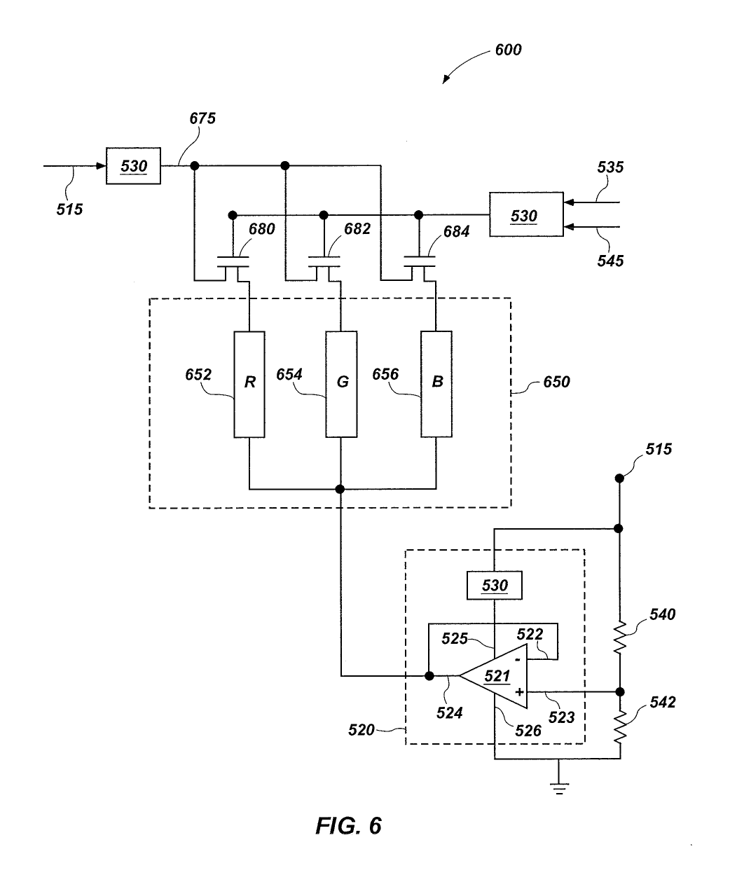

The boost signal 515 may also be provided to the LCD panel 550 in order to drive the appropriate components with a relatively higher voltage. The boost signal 515 may drive a column driver (not shown, see FIG. 6) that selects the appropriate column of pixels within the LCD panel 550. The boost signal 515 may also be provided to the gate high voltage converter 530, which generates a gate high signal 535 that is a relatively higher voltage than the boost signal 515. The boost signal 515 may also be provided to the gate low voltage converter 540, which generates a gate low signal 545 that is a relatively lower voltage than the boost signal 515. For example, the gate low signal 545 may be a negative voltage. The gate high voltage converter 530 and the gate low voltage converter 540 may be coupled with the LCD panel 550, and the gate high signal 535 and the gate low signal 545 may be provided to the LCD panel 550. For example, the gate high signal 535 and the gate low signal 545 may be provided to a row driver (not shown; see FIG. 6) of the LCD panel 550 in order to select the appropriate row of pixels within the LCD panel 550.

FIG. 6 is a simplified block diagram of another portion of an electronic display system 600 according to an embodiment of the present invention. The electronic display system 600 includes a V_{COM} driver 520 including an operational amplifier 521 and a voltage converter 530 configured as previously discussed with respect to FIG. 5. The electronic display system 600 further includes a pixel 650, a row driver 660, a column driver 670, and a plurality of transistors 680, 682, 684. The pixel 650 includes sub-pixels that include a red (R) sub-pixel 652, a green (G) sub-pixel 654, and a blue (B) sub-pixel 656. The electronic display system 600 shown may be a portion of an overall electronic display system, and may include an array of pixels (not shown), with each pixel of the array being configured similarly as the pixel 650 shown in FIG. 6. While a standard RGB configuration is shown in FIG. 6, other configurations and combinations of sub-pixel colors are also contemplated. The plurality of transistors 680, 682, 684 may be thin-film transistors (TFT).

The plurality of transistors 680, 682, 684 are coupled with the pixel 650 such that a first transistor 680 is coupled with the red (R) sub-pixel 652, a second transistor 682 is coupled with the green (G) sub-pixel 654, and a third transistor 684 is coupled with the blue (B) sub-pixel 656. The gates for each transistor of the plurality of transistors 680, 682, 684 are coupled with the row driver 660. The row driver 660 is configured to activate a row of pixels in an array of pixels (not shown) in response to the gate high signal 535 and the gate low signal 545 (FIG. 5). The plurality of transistors 680, 682, 684 are also coupled with the column driver 670. The column driver 670 is configured to apply an analog control voltage 675 to each sub-pixel 652, 654, 656 in order to activate a column of pixels in an array of pixels (not shown), and in which the column driver 670 is driven by the boost signal 515. The actual selection of a column and row within the array of pixels by the column driver 670 and the row driver 660 may be controlled by a control signal transmitted to the column driver 670 and the row driver 660 by a controller (not shown).

The V_{COM} driver 520 is coupled with the pixel 650. The V_{COM} driver is configured to maintain a common analog reference voltage (V_{COM}) for the pixels (e.g., pixel 650) of the array of pixels (not shown). The V_{COM} driver 520 may be configured as previously described in FIG. 5 and in accordance with the other embodiments of the present invention.

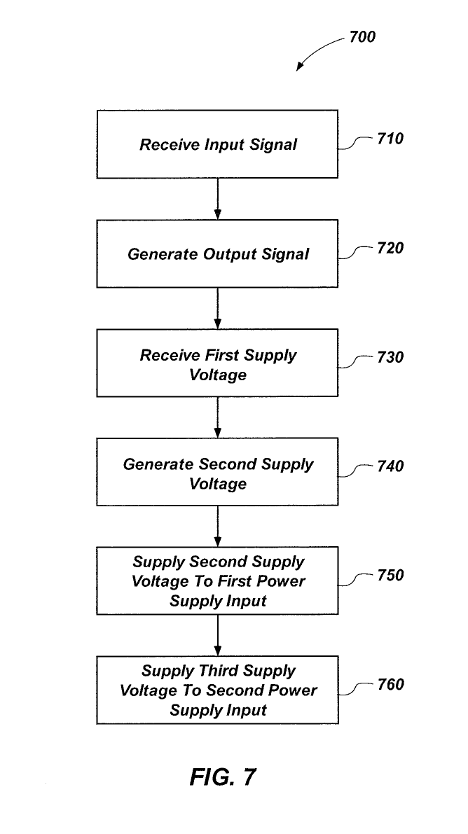

FIG. 7 is a flow chart 700 illustrating a method for generating a signal from an operational amplifier according to an embodiment of the present invention. At operation 710, an input signal is received by an operational amplifier. The input signal may be received by a non-inverting input of the operational amplifier. At operation 720, an output signal (e.g., V_{COM} signal) is generated by the operational amplifier in response to receiving the input signal. The output signal may be known to operate within a predetermined voltage range. At operation 730, a first supply voltage (e.g., boost signal) is received. The first supply voltage may be received by a voltage converter.

At operation 740, a second supply voltage is generated in response to receiving the first supply voltage. The second supply voltage has a voltage that is different from the first supply voltage. The difference between the voltage of the first power supply input (i.e., the second supply voltage) and the voltage of the output signal may be relatively less than the difference between the first supply voltage (e.g., boost signal) and the output signal (V_{COM} signal). In other words, the second supply voltage more closely resembles the voltage of the expected operating range of the output signal than does the first supply voltage. In some embodiments, the difference between the second voltage supply and the voltage of the output signal may be approximately equal to zero. At operation 750, the second power supply signal supplied to a first power supply input of the operational amplifier. At operation 760, a third supply voltage is supplied to a second power supply input of the operational amplifier. The third supply voltage may be approximately 0V. In other words, the second power supply input of the operational amplifier may be coupled with ground.

While the present invention has been described herein with respect to certain illustrated embodiments, those of ordinary skill in the art will recognize and appreciate that the present invention is not so limited. Rather, many additions, deletions, and modifications to the illustrated and described embodiments may be made without departing from the scope of the invention as hereinafter claimed along with their legal equivalents. In addition, features from one embodiment may be combined with features of another embodiment while still being encompassed within the scope of the invention as contemplated by the inventor.

What is claimed is:

1. An amplifier, comprising:
an operational amplifier including an inverting input, a non-inverting input, an output, a first power supply input and a second power supply input, the operational amplifier configured to generate an output signal in response to an input signal; and
a voltage converter operably coupled with the first power supply input of the operating amplifier, wherein the voltage converter is configured to receive a first supply voltage and generate a second supply voltage to the first power supply input of the operational amplifier, wherein a voltage of the second supply voltage is relatively closer to the expected operating voltage range of the output signal than the first supply voltage.

2. The amplifier of claim 1, wherein the operational amplifier and the voltage converter are housed within a common package.

3. The amplifier of claim 2, wherein the operational amplifier and the voltage converter are fabricated within a common integrated circuit.

4. The amplifier of claim 2, wherein the voltage converter is a charge pump device.

5. The amplifier of claim 4, wherein the charge pump device includes a switch network operably coupled with an oscillator and logic module, wherein the oscillator and logic module is configured to activate the switch network in order to toggle between charging and discharging a flying capacitor and generate the desired second supply voltage over a load capacitor coupled therewith.

6. The amplifier of claim 2, wherein the second supply voltage generated by the voltage converter is a reduced voltage of the first power supply voltage.

7. The amplifier of claim 6, wherein the reduced voltage is approximately one half of the first power supply voltage.

8. The amplifier of claim 2, wherein the second supply voltage generated by the voltage converter is an increased voltage of the first power supply voltage.

9. The amplifier of claim 2, further comprising a plurality of operational amplifiers, wherein each operational amplifier of the plurality includes an inverting input, a non-inverting input, an output, a first power supply input and a second power supply input, and wherein each first power supply input of the plurality of operational amplifiers is operably coupled with the voltage converter.

10. The amplifier of claim 1, wherein the second power supply input is coupled with ground.

11. The amplifier of claim 1, wherein the operational amplifier is configured as a buffer with the inverting input of the operational amplifier coupled with the output of the operational amplifier.

12. A method for operating an operational amplifier, the method comprising:
receiving an input signal at an input of an operational amplifier;
generating an output signal at an output of the operational amplifier in response to receiving the input signal;
receiving a first supply voltage;
generating a second supply voltage in response to receiving the first supply voltage;
supplying the second supply voltage to a first power supply input of the operational amplifier, wherein the second supply voltage is relatively closer to a voltage level of the output signal than is the first supply voltage.

13. The method of claim 12, wherein receiving an input signal includes receiving a boost signal generated by a boost regulator, the boost signal having a voltage greater than a voltage of a system input signal.

14. The method of claim 12, further comprising transmitting the output signal to a common voltage reference of an electronic display.

15. The method of claim 12, wherein generating an output signal includes generating the output signal to be approximately equal to the input signal with the operational amplifier being configured as a buffer.

16. The method of claim 15, wherein receiving an input signal includes receiving an input signal at the input of the operational amplifier that is a non-inverting input.

17. The method of claim 12, wherein generating the second supply voltage includes generating the second supply voltage to be reduced from the first power supply signal.

18. The method of claim 12, wherein generating the second supply voltage includes generating the second power supply signal to be approximately equal to the voltage level of the output signal.

19. An electronic display system, comprising:
a pixel array;
a boost regulator configured to generate a boost signal;
an operational amplifier operably coupled between the boost regulator and the pixel array, the operational amplifier configured to generate a common voltage reference signal to the pixel array; and
a voltage converter operably coupled between the boost regulator and a first power supply input of the operational amplifier, the voltage converter configured to receive the boost signal and generate a supply voltage to the first power supply input of the operational amplifier, wherein the supply voltage has a voltage that is relatively closer to a voltage of the common voltage reference signal than does a voltage of the boost signal.

20. The electronic display system of claim 19, wherein the operational amplifier is configured as a voltage follower.

21. The electronic display system of claim 19, wherein the voltage converter is a charge pump.

22. The electronic display system of claim 19, wherein the voltage converter and the operational amplifier are housed within a common package.

23. The electronic display system of claim 19, wherein the supply voltage is approximately half of a voltage of the boost signal.

24. The electronic display system of claim 19, wherein the supply voltage is approximately equal to the common voltage reference signal.

25. The electronic display system of claim 19, further comprising a plurality of operational amplifiers operably coupled between the boost regulator and the pixel array, wherein each operational amplifier of the plurality is configured to generate a common voltage reference signal to a different portion of the pixel array.
